(19) United States
(12) Patent Application Publication
(10) Pub. No.: US 2026/0336058 A1
(43) Pub. Date: Oct. 29, 2026

(54) WAFER POLISHING SYSTEM

(71) Applicant: HANGZHOU SIZONE ELECTRONIC TECHNOLOGY INC., Zhejiang (CN)

(72) Inventor: Xiaoyu XU, Zhejiang (CN)

(73) Assignee: HANGZHOU SIZONE ELECTRONIC TECHNOLOGY INC., Zhejiang (CN)

(21) Appl. No.: 18/995,925

(22) PCT Filed: Oct. 16, 2023
(86) PCT No.: PCT/CN2023/124672

§ 371 Date: Jan. 17, 2025

(30) Foreign Application Priority Data
Oct. 18, 2022 (CN) 202211269445.0

(51) Int. Cl. B24B 37/34; B24B 37/04; B24B 41/06; H10P 72/00

(52) U.S. Cl. CPC B24B 37/345; B24B 37/04; B24B 41/06; H10P 72/0428

(57) ABSTRACT

A wafer polishing system includes at least two polishing units, wherein each polishing unit includes at least two polishing modules and a first fixed working station, and each polishing module includes a polishing platform and a polishing head; at least two polishing heads in each polishing unit are able to transfer wafers to the first fixed working station; at least a second fixed working station is arranged between adjacent polishing units; at least two polishing heads of adjacent polishing units are able to transfer the wafers to the second fixed working station.

### TECHNICAL FIELD

The invention belongs to the technical field of fabrication of semiconductor integrated circuit chips, and particularly relates to a wafer polishing system.

### DESCRIPTION OF RELATED ART

It is found, in an actual wafer processing process, that the spatial arrangement of polishing units, i.e. cleaning module, wafer transfer module and other modules has a great influence on the overall polishing output of chemical mechanical planarization (CMP) devices. Wafer transfer between the polishing units and the outside as well as between the polishing units is implemented generally by means of a loading and unloading platform.

As for the spatial arrangement of the loading and unloading platform and the polishing units, most CMP devices on the market adopts a square arrangement of the loading and unloading platform and three polishing units. Four polishing heads are fixed on a cross-shaped rotary workbench, which means that each wafer entering the polishing area corresponds to one polishing head, one loading and unloading platform provides the loading and unloading service for three polishing units, the number of the polishing heads and the number of polishing platforms cannot be adjusted, and the polishing time of each polishing head cannot be separately controlled, leading to poor timeliness and low flexibility; and liquids on different polishing platforms are prone to splash to result in a cross influence, compromising the polishing effect and leading to a complex process.

In view of the above problems, CMP devices with multiple polishing units arranged in parallel emerge on the market, wherein each polishing unit comprises at least two polishing modules, which share a same fixed working station, such that the space of the devices is compact, and the wafer transfer efficiency is high. However, in some process cases, higher wafer transfer efficiency is required.

### SUMMARY

To overcome the defects in the prior art, the invention provides a wafer polishing system, which has high wafer transfer flexibility and higher wafer transfer efficiency.

The technical solution adopted by the invention to solve the technical problems is as follows: a wafer polishing system comprises at least two polishing units, wherein:
each polishing unit comprises at least two polishing modules and a first fixed working station, and each polishing module comprises a polishing platform and a polishing head;
at least two polishing heads in each polishing unit are able to transfer wafers to the first fixed working station;
at least a second fixed working station is arranged between adjacent polishing units;
at least two polishing heads of adjacent polishing units are able to transfer the wafers to the second fixed working station.

Further, a third fixed working station is arranged between adjacent polishing units.

Further, movement areas of the polishing heads of two polishing modules of adjacent polishing units have an overlap, and the second fixed working station is located in the overlap.

Further, an axis of the second fixed working station is located in the overlap.

Further, the second fixed working station is a loading and unloading platform, or a combination of the loading and unloading platform and a cleaning component, or a cleaning station, or a robot arm.

Further, an axis of the second fixed working station and an axis of a third working station are located at intersections of the overlap.

Further, the second fixed working station and the third fixed working station are respectively a cleaning station and a loading and unloading platform.

Further, a movement trajectory of each polishing head is arc or circular, movement trajectories of centers of the polishing heads of two polishing modules in each polishing unit have only one intersection, and an overlap of the movement trajectories of the centers of the two polishing heads in a diagonal direction of adjacent polishing units is eye-shaped.

Further, an axis of the second fixed working station and an axis of the third fixed working station are located at intersections of the overlap of the movement trajectories of the centers of the polishing heads.

Further, at least a cleaning station and a loading and unloading platform are arranged in the movement trajectories of the centers of the polishing heads of the polishing unit at an end of the wafer polishing system.

Further, an overlap of movement trajectories of centers of the polishing heads of two polishing modules in each polishing unit is eye-shaped, and an overlap of movement trajectories of centers of the polishing heads of the two polishing modules in a diagonal direction of adjacent polishing units is eye-shaped.

Further, an overlap of movement trajectories of centers of the polishing heads of two polishing module in each polishing unit is eye-shaped, and movement trajectories of centers of the polishing heads of the two polishing modules in a diagonal direction of adjacent polishing units has only one intersection.

Further, movement trajectories of centers of the polishing heads of two polishing module in each polishing unit has only one intersection, and movement trajectories of centers of the polishing heads of the two polishing modules in a diagonal direction of adjacent polishing units is has only one intersection.

Further, a movement area of the polishing head of at least one polishing module of each polishing unit passes through an axis of the first fixed working station and an axis of the second fixed working station.

Further, at least two first fixed working stations are arranged in each polishing unit; the two polishing heads corresponding to only one first fixed working station in adjacent polishing units are arranged close to each other, and the second fixed working station is between the two polishing heads.

Further, connecting lines between the polishing modules in adjacent polishing units are parallel, and the second fixed working station is located between the polishing modules in a diagonal direction of adjacent polishing units.

Further, connecting lines between polishing modules in adjacent polishing units intersect with each other, and the second fixed working station is close to an intersection of the connecting lines.

Further, the polishing units are arranged in a wafer transfer direction, and a transfer interval is formed between adjacent polishing units.

Further, multiple polishing units are arranged along a straight line, or an oblique line, or a bend line.

Further, each polishing unit is provided with two polishing modules.

Further, at least two first fixed working stations are arranged in each polishing unit; the two polishing heads corresponding to only one first fixed working station are close to each other, and the second fixed working station is arranged between the two polishing heads.

The invention has the following merits: (1) the first fixed working station, the second fixed working station and the polishing heads work together to realize wafer transfer between polishing areas in the polishing system, and the transfer flexibility is better; (2) the second fixed working station is added, the polishing heads of the polishing modules of adjacent polishing units can fetch a wafer from the third fixed working station or place a wafer onto the third fixed working station, such that wafers are transferred between the polishing modules of the adjacent polishing units and are transferred between the polishing areas to be polished; (3) the second fixed working station and the third fixed working station are added, such that the polishing heads can swing to the position right above a loading and unloading platform to be cleaned, the whole wafer transfer process is more complete and faster; (4) the second fixed working station and the third fixed working station are added, such the cleanliness of the polishing heads is guaranteed without affecting wafer transfer, and the product yield is increased; (5) a traditional working condition where wafers wait for polishing heads is changed, the transfer speed of the polishing heads is increased, and the wafer polishing efficiency is improved; (6) the transfer path can be diversified freely, the wafer transfer path may be a straight line, a curved line or a bend line, and the polishing units may be arranged in more possible ways to adapt to different processes, such that the applicability is better; (7) the polishing arm of each polishing module is controlled separately, such that the stability and flexibility are better; (8) the working time of each polishing module can be controlled separately to satisfy different polishing requirements; (9) one fixed working station can receive wafers from and dispatch wafers to polishing modules on two sides and does not need to be moved to be close to the left or right polishing module, such that position adjustment is easier and more accurate; (10) by means of the transfer interval, cross contamination of different polishing processes between adjacent polishing units can be avoided, the polishing units can be maintained easily, and processing gets easier.

### BRIEF DESCRIPTION OF THE DRAWINGS

FIG. 1 is a schematic diagram of two polishing units according to Embodiment 1 of the invention.

FIG. 2 is a schematic diagram of three polishing units according to Embodiment 1 of the invention.

FIG. 3 is a schematic diagram in a case where a robot arm is arranged on a second fixed working station according to Embodiment 1 of the invention.

FIG. 4 is a schematic diagram of a wafer polishing system according to Embodiment 2 of the invention.

FIG. 5 is a schematic diagram of a wafer polishing system according to Embodiment 3 of the invention.

FIG. 6 is a first schematic diagram of a wafer polishing system according to Embodiment 4 of the invention.

FIG. 7 is a second schematic diagram of the wafer polishing system according to Embodiment 4 of the invention.

FIG. 8 is a first schematic diagram of a wafer polishing system according to Embodiment 5 of the invention.

FIG. 9 is a second schematic diagram of the wafer polishing system according to Embodiment 5 of the invention.

FIG. 10 is a schematic diagram of a wafer polishing system according to Embodiment 6 of the invention.

FIG. 11 is a structural diagram of part A in FIG. 10.

FIG. 12 is a structural diagram of part B in FIG. 10.

FIG. 13 is a partial schematic diagram of a wafer polishing system according to Embodiment 7 of the invention.

FIG. 14 is a schematic diagram of the wafer polishing system according to Embodiment 7 of the invention.

FIG. 15 is a partial schematic diagram of a wafer polishing system according to Embodiment 8 of the invention.

FIG. 16 is a partial schematic diagram of a wafer polishing system according to Embodiment 9 of the invention.

FIG. 17 is a partial schematic diagram of a wafer polishing system according to Embodiment 9 of the invention.

Wherein: 1, polishing unit; 2, polishing module; 21, polishing platform; 22, polishing head; 221, first polishing head; 222, second polishing head; 223, third polishing head; 224, fourth polishing head; 3, first fixed working station; 31, another first fixed working station; 32, first fixed working station II; 33, first fixed working station III; 34, first fixed working station IV; 35, first fixed working station V; 4, second fixed working station; 5, overlap; 51, intersection of overlap; 6, transfer interval; 7, third fixed working station.

### DETAILED DESCRIPTION OF THE EMBODIMENTS

To allow those skilled in the art to have a better understanding of the technical solutions of the invention, the technical solutions in the embodiments of the invention will be clearly and completely described below in conjunction with accompanying drawings of these embodiments. Obviously, the embodiments described below are merely illustrative ones, and are not all possible ones of the invention. All other embodiments obtained by ordinarily skilled in the art based on the following ones without creative labor should also fall within the protection scope of the invention.

### Embodiment 1

A wafer polishing system comprises at least two polishing units 1.

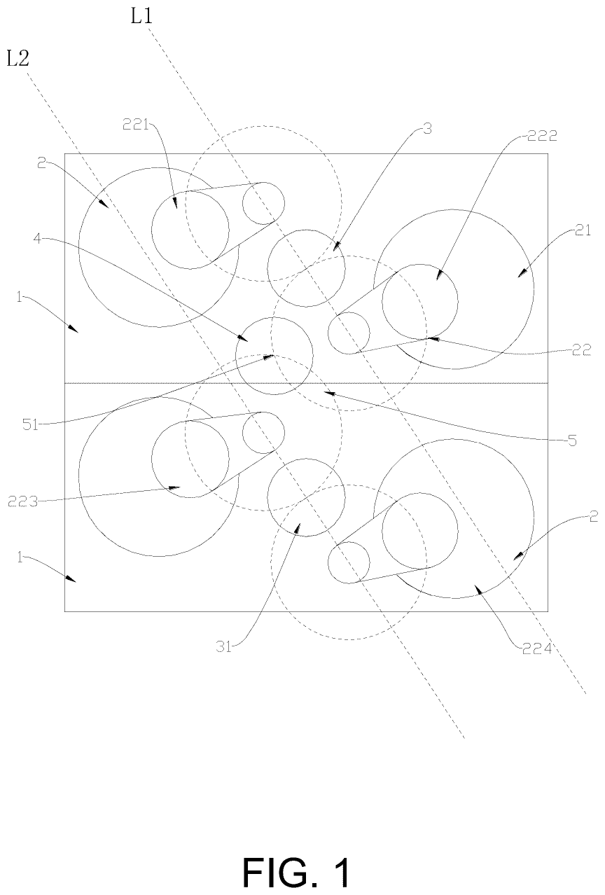

As shown in FIG. 1, each polishing unit 1 comprises at least two polishing modules 2 and a first fixed working station 3. Each polishing module 2 comprises a polishing platform 21 and a polishing head 22, wherein the polishing head 22 is able to drive a wafer to move with respect to the polishing platform 21 to implement a polishing process. Here, “move” may refer to a synchronous movement of the wafer with the polishing head 22 or a relative movement between the wafer and the polishing head 22. The polishing heads 22 of the at least two polishing modules 2 in each polishing unit 1 are able to transfer wafers to the first fixed working station 3.

Moreover, at least a second fixed working station 4 is arranged between adjacent polishing units 1. At least two polishing heads 22 of the adjacent polishing units 1 (two polishing units are provided with at least four polishing heads) are able to transfer wafers to the second fixed working station 4.

Specifically, a first polishing head 221 of an upstream polishing unit 1 is able to transfer a wafer to the first fixed working station 3, and a second polishing head 222 of the upstream polishing unit 1 is able to transfer a wafer to the first fixed working station 3. Meanwhile, the second polishing head 222 of the upstream polishing head 1 is able to transfer a wafer to the second fixed working station 4, and a third polishing head 223 of a downstream polishing unit 1 is able to transfer a wafer to the second fixed working station 4. In other words, the first fixed working station 3 corresponds to the first polishing head 221 and the second polishing head 222 of the upstream polishing unit 1, the second polishing head 222 corresponds to the first fixed working station 3 and the second fixed working station 4, and the third polishing head 223 corresponds to the fixed working station 3 and the second fixed working station 4.

Movement areas of the polishing heads 22 of two polishing modules 2 of the adjacent polishing units 1 have an overlap 5, and the second fixed working station 4 is located in the overlap 5.

Specifically, a movement area of the second polishing head 222 of the upstream polishing unit 1 and a movement area of the third polishing head 223 of the downstream polishing unit 1 have an overlap 5, and the second fixed working station 4 is located in the overlap 5.

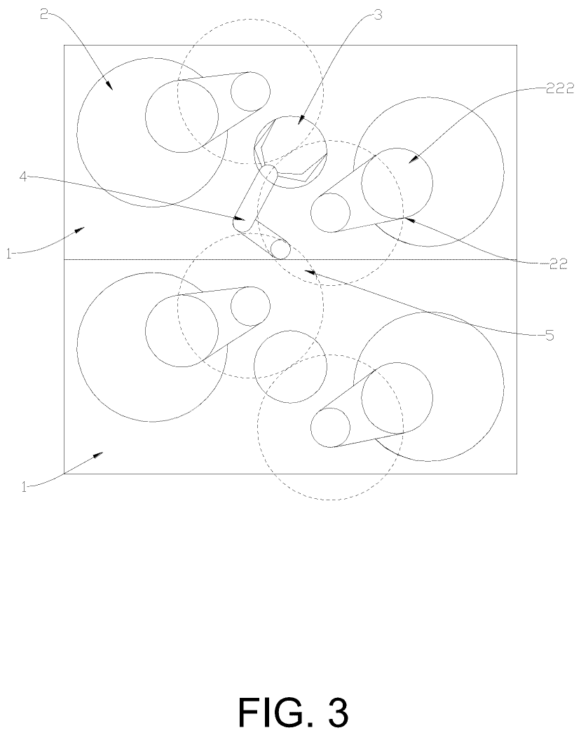

More specifically, the axis of the second fixed working station 4 is located in the overlap 5. Further specifically, the axis of the second fixed working station 4 is located at an intersection 51 of the overlap. In this embodiment, a wafer loading and unloading platform or a robot arm (an existing structure) may be arranged on the second fixed working station 4, and in this case, the center of the wafer loading and unloading platform is located at the intersection 51 of the overlap, or the axis of rotation of the robot arm is located at the intersection 51 of the overlap, as shown in FIG. 3. Of course, the second fixed working station 4 may be a combination of a loading and unloading platform and a cleaning component or the second fixed working station 4 may be a cleaning station. Here, the cleaning station may not be provided with a specific structure, and sprayers may be installed on the cleaning station.

In this embodiment, each polishing unit 1 is provided with two polishing modules 2, and a wafer loading and unloading platform is arranged on the second fixed working station 4. As can be seen from FIG. 1, the second polishing head 222 has an arc movement trajectory, or has a large rotation amplitude and a circular movement trajectory, and the movement trajectory of the second polishing head 222 passes through the axis of the fixed working station 3 and the axis of the second fixed working station 4. The third polishing head 223 has an arc movement trajectory, or has a large rotation amplitude and a circular movement trajectory, and the movement trajectory of the third polishing head 223 passes through the axis of another first fixed working station 3 and the axis of the second fixed working station 4. In this way, an overlap between movement trajectories of the centers of the second polishing head 222 and the third polishing head 223 is eye-shaped, that is to say, movement trajectories of the centers of the polishing heads of two polishing modules of adjacent polishing units is eye-shaped; the axis of the second fixed working station 4 is located at an internal or external corner of the eye-shaped overlap, that is, the axis of the second fixed working station 4 is located at an intersection of the movement trajectories of the centers of the polishing heads of two polishing modules of adjacent polishing units.

Connecting lines between the polishing modules in the adjacent polishing units 1 are parallel. As shown in FIG. 1, a connecting line between the axes of rotation of the polishing heads 22 of the two polishing module 2 of the upstream polishing unit 1 is L1, and a connecting line between the axes of rotation of the polishing heads of the two polishing modules of the downstream polishing unit is L2, and L1 is parallel to L2. In this case, the second fixed working station 4 is located between the polishing modules in a diagonal direction of the adjacent polishing units, to be exact, the second fixed working station 4 is between two close polishing modules in the diagonal direction of the adjacent polishing units, that is, the second fixed working station 4 is located between the polishing module to which the second polishing head 222 belongs and the polishing module to which the third polishing head 223 belongs.

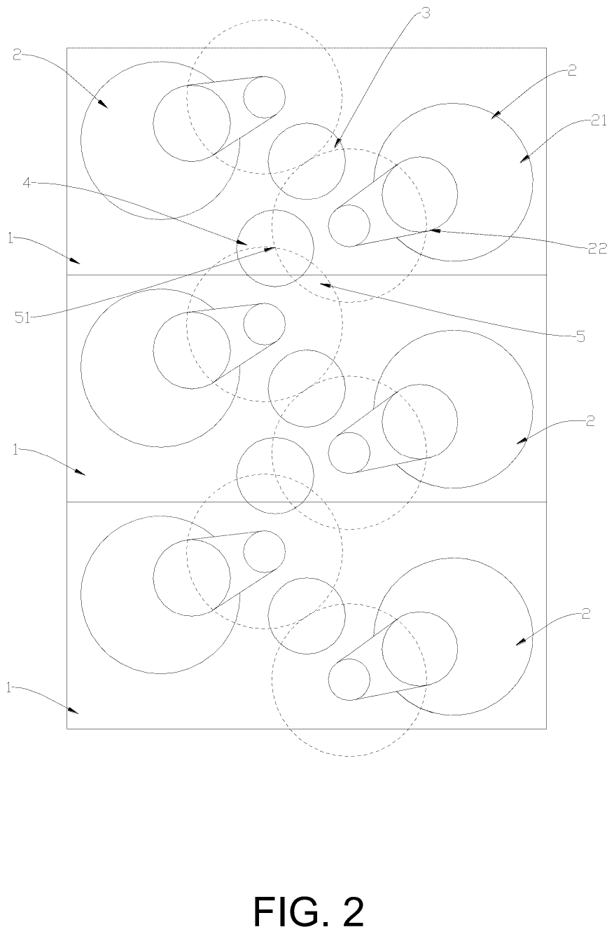

As shown in FIG. 2, multiple polishing units 1 are arranged along a straight line. In this embodiment, with the directions shown in FIG. 2 as an example, the polishing unit located above is defined as the upstream polishing unit, and the polishing unit located below is defined as the downstream polishing unit. The specific process sequence of the polishing system is not limited and is merely for the purpose of facilitating description.

### Embodiment 2

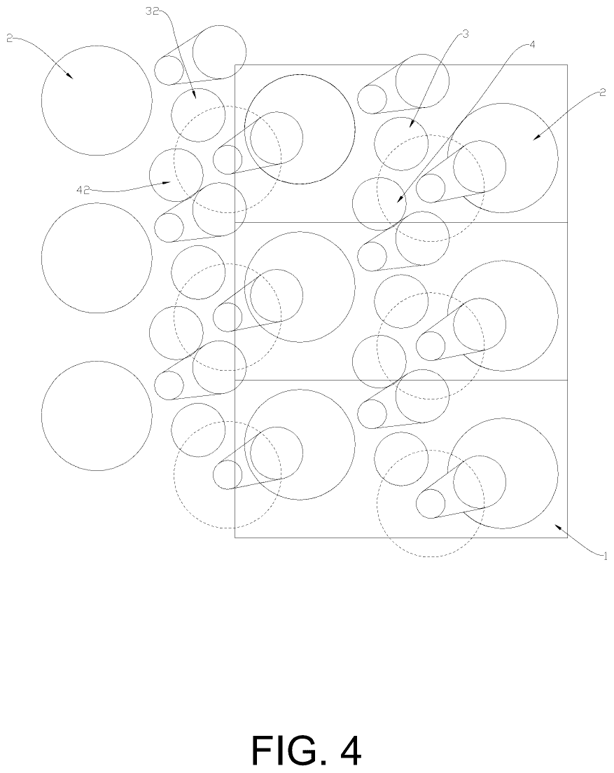

As shown in FIG. 4, based on Embodiment 1, polishing modules may be added on the left. In this case, the polishing module on the left and the polishing module in the middle share a first fixed working station II 32, and a second fixed working station I 41 is arranged below the first fixed working station II 32; the polishing module in the middle and the polishing module on the right share the first fixed working station 2, and the second fixed working station 4 is arranged below the first fixed working station 3.

In other words, polishing modules may be added in a width direction. In this case, each polishing unit 1 comprises three polishing modules 2.

### Embodiment 3

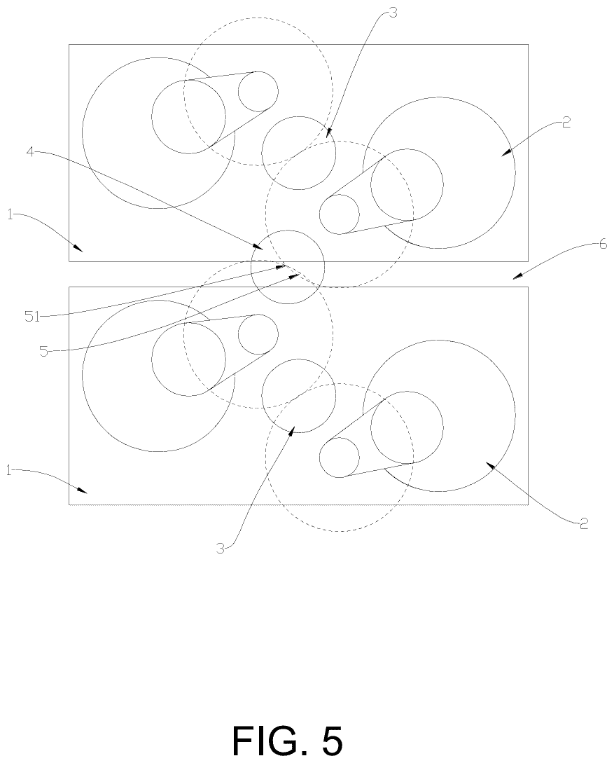

As shown in FIG. 5, the polishing units 2 are arranged in a wafer transfer direction, which is a vertical direction in FIG. 5, a transfer interval 6 is located between adjacent polishing units, and the second fixed working station 4 is located in the transfer interval 6.

By means of the transfer interval, cross contamination of different polishing processes between the adjacent polishing units can be avoided, the polishing units can be maintained easily, and processing is easier.

This embedment is identical with Embodiment 1 in other aspects and will not be repeated.

### Embodiment 4

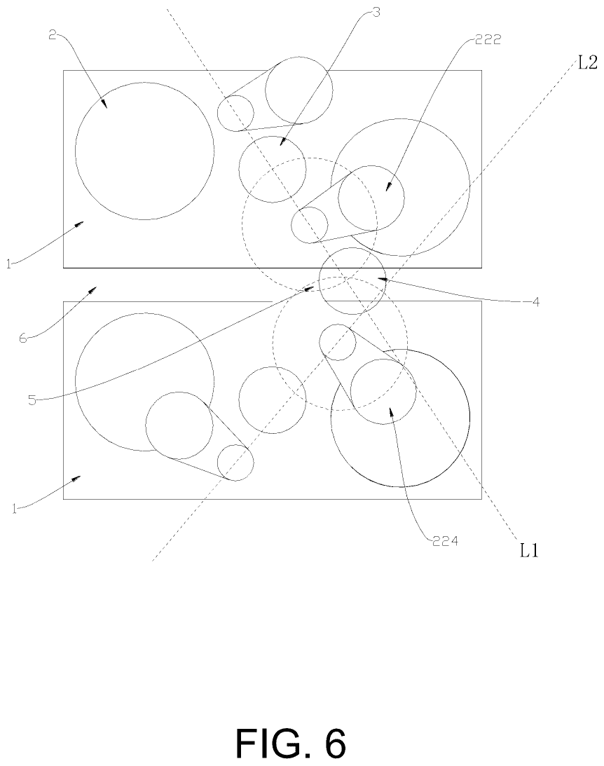

As shown in FIG. 6, this embodiment is different from Embodiment 1 in that connecting lines between polishing modules in adjacent polishing units intersect with each other. A connecting line between the axes of rotation of the polishing heads 22 of the two polishing modules 2 of the upstream polishing unit 1 is L1, a connecting line between the axes of rotation of the polishing heads of the two polishing modules of the downstream polishing unit is L2, and L1 intersects with L2. In this case, the second fixed working station 4 is located between the polishing modules on a same side of the adjacent polishing units, that is, the second fixed working station 4 is located between the polishing module to which the second polishing head 222 belongs and the polishing module to which a fourth polishing head 224 belongs. In this case, the second fixed working station 4 is in the vicinity of an intersection of L1 and L2. That is to say, the second fixed working station 4 is close to a perpendicular bisector of the two polishing modules on the same side of the adjacent polishing units or the second fixed working station 4 is close to a perpendicular bisector of the polishing modules in the diagonal direction of the adjacent polishing units. Here, the perpendicular bisector of the polishing modules may be a perpendicular bisector of polishing platforms or a perpendicular bisector of the axes of rotation of polishing heads, and the invention has no specific limitation in this aspect.

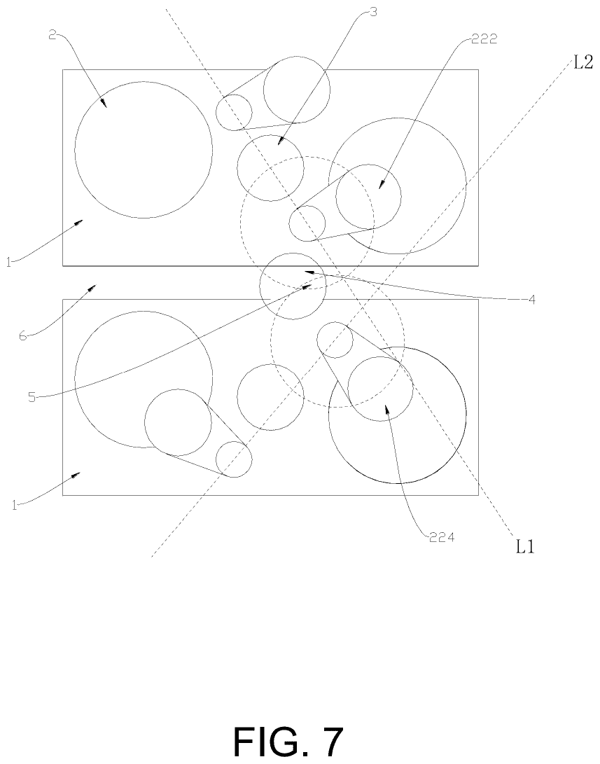

As shown in FIGS. 6 and 7, the second fixed working station 4 may be located at both the internal and external corners of the eye-shaped overlap in Embodiment 1.

This embodiment is identical with Embodiment 1 or Embodiment 3 in other aspect and will not be repeated here.

### Embodiment 5

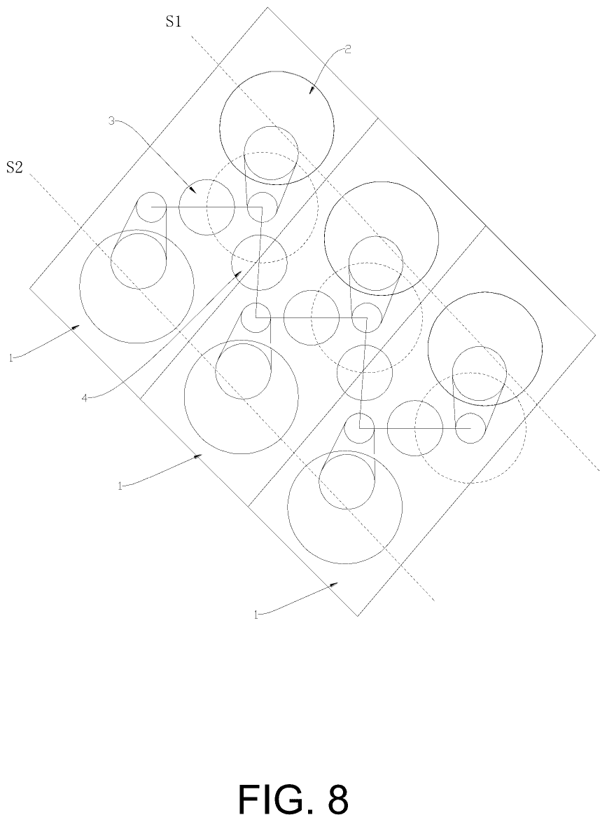

As shown in FIG. 8, the polishing units 1 are arranged along an oblique line. That is, the polishing modules on one side of the polishing units 1 are arranged in a direction S1, the polishing modules on the other side of the polishing units 1 are arranged in in a direction S2, and S1 is parallel to S2.

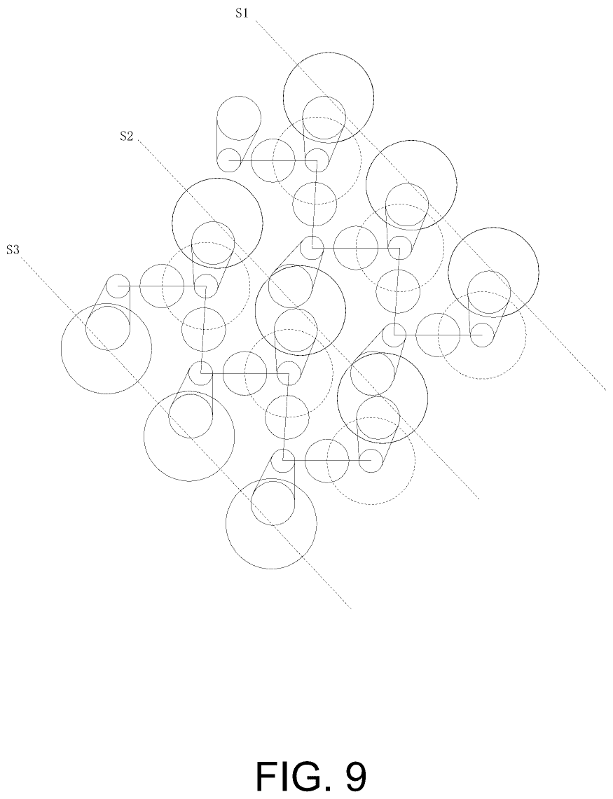

As shown in FIG. 9, polishing modules may be added in the polishing units 1 in a width direction, that is, the polishing modules on the left of the polishing units 1 are arranged in a direction S3, the polishing modules in the middle are arranged in the direction S2, the polishing modules on the right are arranged in the direction S1, and S1, S2 and S3 are parallel to each other.

This embodiment is identical with Embodiment 1 or Embodiment 3 in other aspects and will not be repeated here.

### Embodiment 6

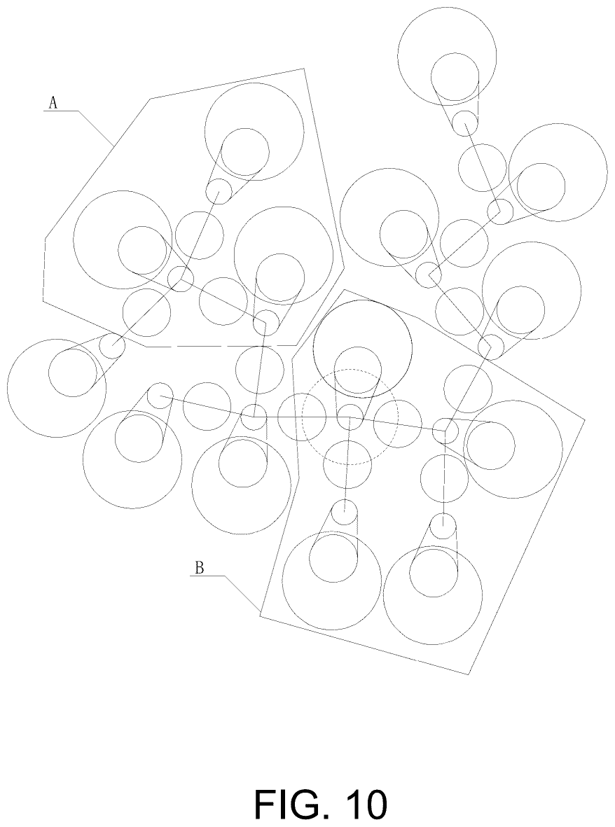

As shown in FIG. 10, the polishing units 1 are arranged along a bend line. In this case, the number of polishing modules in each polishing unit 1 may be different. The polishing modules, the first fixed working station and the second fixed working station may be arranged in various ways, such that wafer transfer paths are diversified.

Of course, in other embodiments, the polishing units 1 may be arranged along a curved line.

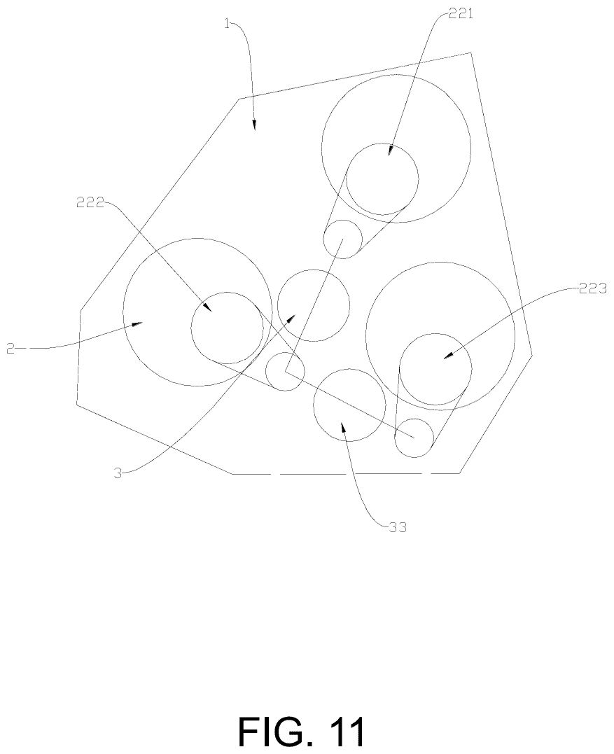

As shown in FIG. 11, in this case, one polishing unit 1 comprises three polishing modules, a first fixed working station 3 and a first fixing working station III 33. The first fixed working station 3 correspondingly serves the first polishing head 221 and the second polishing head 222, the first fixed working station 33 correspondingly serves the second polishing head 222 and the third polishing head 223, and the second polishing head 222 corresponds to the first fixed working station 3 and first fixed working station III 33.

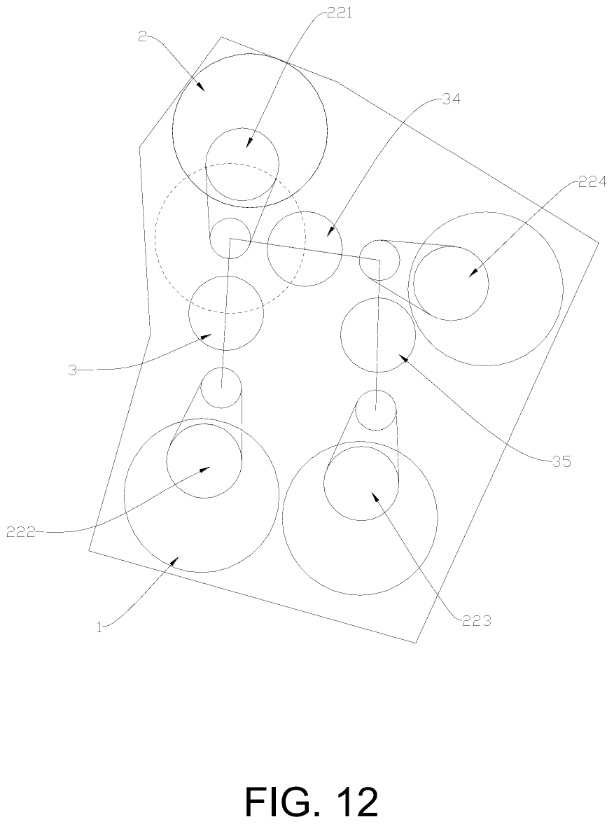

As shown in FIG. 12, one polishing unit 1 comprises four polishing modules, a first fixed working station 3, a first fixed working station IV and a first fixed working station V 35. The first fixed working station 3 correspondingly serves the first polishing head 221 and the second polishing head 222, the first fixed working station IV 34 correspondingly serves the first polishing head 221 and the fourth polishing head 224, and the first fixed working station V 35 correspondingly serves the third polishing head 223 and the fourth polishing head 224. The first polishing head 221 corresponds to the first fixed working station 3 and the first fixed working station IV 34, and the fourth polishing head 224 corresponds to the first fixed working station IV 34 and the first fixed working station V 35.

When two smallest polishing units work together, the two polishing heads, corresponding to only one first fixed working station, in the two polishing units are arranged close to each other, and a second fixed working station is arranged between the two polishing heads. Of course, the movement areas of the two polishing heads should have an overlap. The distribution of the polishing modules in the smallest polishing unit is not specifically limited.

This embodiment is identical with Embodiment 1 in other aspects and will not be repeated here.

### Embodiment 7

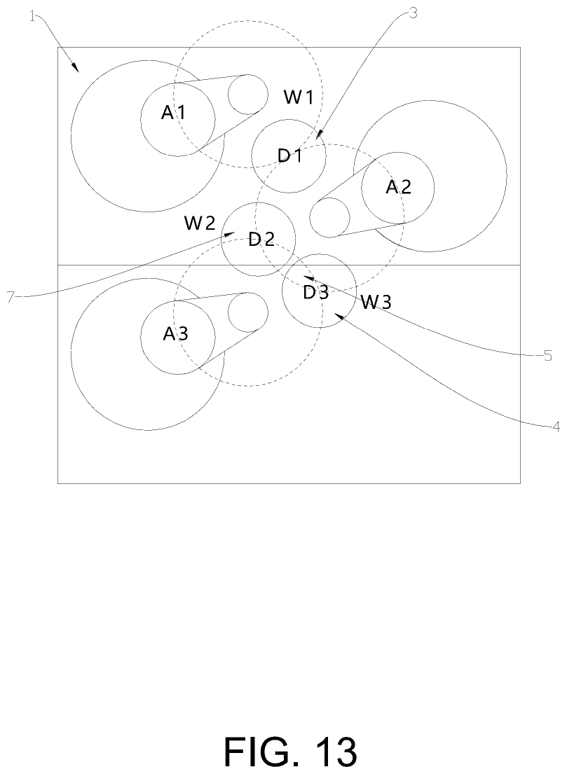

As shown in FIG. 13, a third fixed working station 7 is arranged between adjacent polishing units 1, and the axis of the third fixed working station 7 and the axis of the second fixed working station 4 are both located at the intersection of the overlap 5 in Embodiment 1.

The third fixed working station 7 may be a loading and unloading platform or a cleaning station. Specifically, when the second fixed working station 4 is a cleaning station, the third fixed working station 7 is a loading and unloading platform; when the second fixed working station 4 is a loading and unloading platform, the third fixed working station 7 is a cleaning station.

In this embodiment, the movement trajectories of the centers of the polishing heads 22 of the two polishing modules 2 in each polishing unit 1 have only one intersection D1, and the movement trajectories of the centers of the polishing heads 22 of the two polishing modules 2 in the diagonal direction of adjacent polishing units 1 have an eye-shaped overlap, that is, the movement trajectories of the center of the polishing heads 22 of the two polishing modules 2 in the diagonal direction of the adjacent polishing units 1 have two intersections D2 and D3.

The axis of the second fixed working station 4 and the axis of the third fixed working station 7 are respectively located at the intersections D2 and D3 of the overlap between the movement trajectories of the centers of the polishing heads 22.

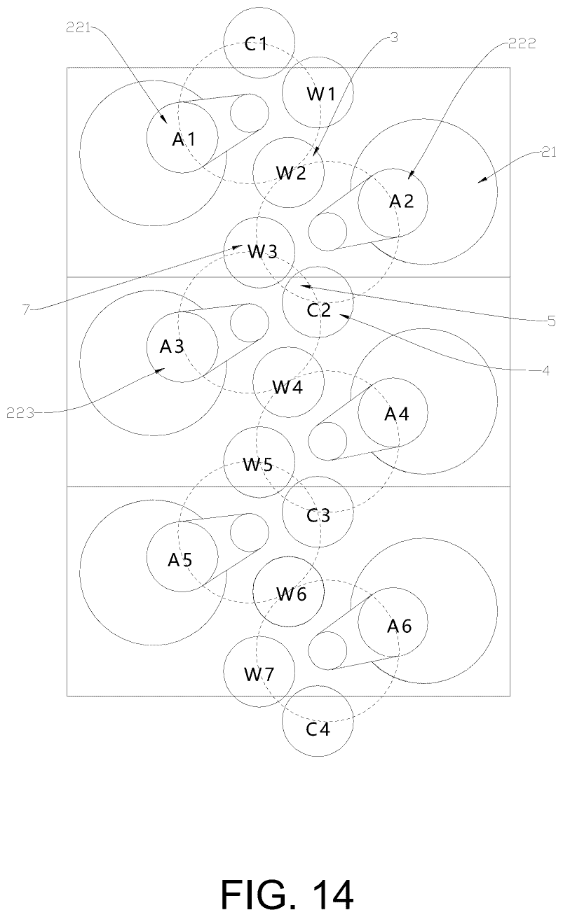

As shown in FIG. 14, at least a cleaning station and a loading and unloading platform are arranged in the movement trajectories of the centers of the polishing heads 22 of the polishing unit 1 at the end of the wafer polishing system.

A cleaning station is defined as C, a loading and unloading platform is defined as W, and a polishing head is defined as A. The polishing head A1 and the polishing head A2 both pass through the first fixed working station 3 (W1). The polishing head A2 and the polishing head A3 both pass through the third fixed working station 7 (W2) and the second fixed working station 4 (W3).

Steps for polishing each wafer three times are as follows:

When a wafer needs to be polished three times, the polishing heads A1, A2 and A3 are used. First, the polishing head A1 fetches the wafer from a loading and unloading platform W1, then rotates to a polishing area to polish the wafer, then places the polished wafer onto a loading and unloading platform W2, and finally rotates to a cleaning station C1 to be cleaned; second, the polishing head A2 fetches the wafer from the loading and unloading platform W1, rotates to the polishing area to polish the wafer, then places the polished wafer onto a loading and unloading platform W3, and finally rotates to a cleaning station C2 to be cleaned; third, the polishing head A1 fetches the wafer from the loading and unloading platform W3, rotates to the polishing area to polish the wafer, then places the polished wafer onto a loading and unloading platform W4, and finally rotates to the cleaning station C2 to be cleaned.

The polishing heads A4, A5, and A6 are used. First, the polishing head A4 fetches the wafer from a loading and unloading platform W4, then rotates to a polishing area to polish the wafer, then places the polished wafer onto a loading and unloading platform W5, and finally rotates to a cleaning station C3 to be cleaned; second, the polishing head A5 fetches the wafer from the loading and unloading platform W5, then rotates to the polishing area to polish the wafer, then places the polished wafer onto a loading and unloading platform W6, and finally rotates to the cleaning station C3 to be cleaned; third, the polishing head A6 fetches the wafer from the loading and unloading platform W6, then rotates to the polishing area to polish the wafer, then places the polished wafer onto a loading and unloading platform W7, and finally rotates to a cleaning station C4 to be cleaned.

After being polished three times, the wafer is transferred by a robot arm to the outside to be cleaned.

Steps for polishing a wafer twice are as follows:
when a wafer needs to be polished twice, the polishing heads A1 and A2 are used. First, the polishing head A1 fetches the wafer from the loading and unloading platform W1, then rotates to the polishing area to polish the wafer, then places the polished wafer onto the loading and unloading platform W2, and finally rotates to the cleaning station C1 to be cleaned; second, the polishing head A2 fetches the wafer from the loading and unloading platform W2, then rotates to the polishing area to polish the wafer, then places the polished wafer onto the loading and unloading platform W3, and finally rotates to the cleaning station C3 to be cleaned.

The polishing heads A3 and A4 are used. First, the polishing head A3 fetches the wafer from the loading and unloading platform W3, then rotates to the polishing area polish the wafer, then places the polished wafer onto the loading and unloading platform W4, and finally rotates to the cleaning station C2 to be cleaned; second, the polishing head A4 fetches the wafer from the loading and unloading platform W4, then rotates to the polishing area to polish the wafer, then places the polished wafer onto the loading and unloading platform W5, and finally rotates to the cleaning station C3 to be cleaned.

The polishing heads A5 and A6 are used. First, the polishing head A5 fetches a wafer from the loading and unloading platform W5, then rotates to the polishing area to polish the wafer, then places the polished wafer onto the loading and unloading platform W6, and finally rotates to the cleaning station C3 to be cleaned; second, the polishing head A6 fetches the wafer from the loading and unloading platform W6, then rotates to the polishing area to polish the wafer, then places the polished wafer onto the loading and unloading platform W7, and finally rotates to the cleaning station C4 to be cleaned.

After being polished twice, the wafer is transferred by a robot arm to the outside to be cleaned.

Steps for polishing a wafer once are as follows:
when a wafer needs to be polished once, for example, the polishing head A1 fetches the wafer from the loading and unloading platform W1, then rotates to the polishing area to polish the wafer, then places the polished wafer onto the loading and unloading platform W2, and finally rotates to the cleaning station C1 to be cleaned.

After being polished once, the wafer is transferred out by a robot arm to the outside to be cleaned.

Of course, the position of the cleaning station C2 and the position of the loading and unloading platform W3 may be exchanged.

### Embodiment 8

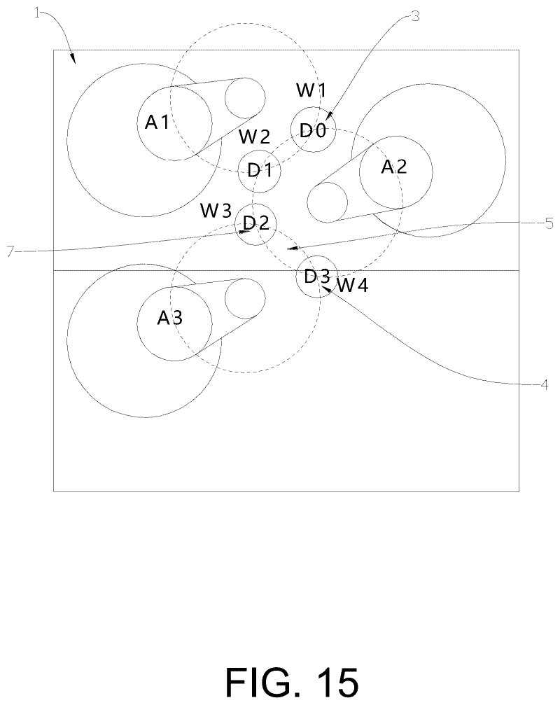

As shown in FIG. 15, in this embodiment, an overlap of movement trajectories of the centers of the polishing heads 22 of two polishing modules 2 in each polishing unit 1 is eye-shaped, that is, the overlap has two intersections D0 and D1. An overlap of movement trajectories of the centers of the polishing heads 22 of two polishing modules 2 in a diagonal direction of adjacent polishing units 1 is eye-shaped, that is, the overlap has two intersections D2 and D3.

That is to say, two first fixed working stations 3 (respectively located at the intersections D0 and D1 of the movement trajectories of the centers) are arranged in each polishing unit 1. The axis of the second fixed working station 4 and the axis of the third fixed working station 7 are respectively located at the intersections D2 and D3 of the overlap of the movement trajectories of the centers of the polishing heads 22.

Two polishing heads, corresponding to only one first fixed working station, in the adjacent polishing units are arranged close to each other, and the second fixed working station is arranged between the two polishing heads. That is, in FIG. 15, the polishing head on the right of the upstream polishing unit and the polishing head on the left of the downstream polishing unit are arranged close to each other, and the second fixed working station 4 (W4) is arranged between the two polishing heads.

The polishing head A1 and the polishing head A2 both pass through the two first fixed working stations 3 (W1 and W2). The polishing head A2 and the polishing head A3 both pass through the third fixed working station 7 (W3) and the second fixed working station 4 (W4).

### Embodiment 9

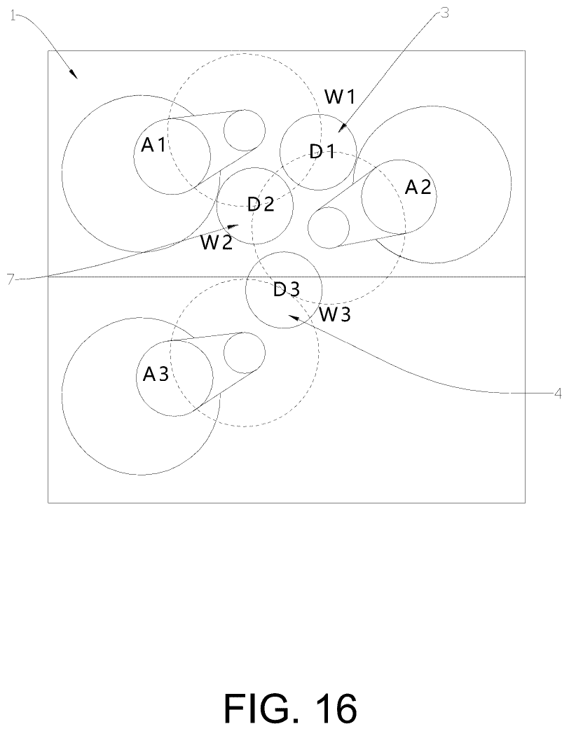

As shown in FIG. 16, in this embodiment, an overlap of movement trajectories of the centers of the polishing heads 22 of two polishing modules 2 in each polishing unit 1 is eye-shaped, that is, the overlap has two intersections D1 and D2. Movement trajectories of the centers of the polishing heads 22 of two polishing modules 2 in a diagonal direction of adjacent polishing units 1 have only one intersection D3.

That is to say, two first fixed working stations 3 (respectively located at the intersections D1 and D2 of the movement trajectories of the centers) are arranged in each polishing unit 1. The axis of the second fixed working station 4 is located at the intersection D3 of the movement trajectories of the centers of the polishing heads 22.

The polishing head A1 and the polishing head A2 both pass through the two first fixed working station 3 (W1 and W2). The polishing head A2 and the polishing head A3 both pass through the second fixed working station 4 (W3).

### Embodiment 10

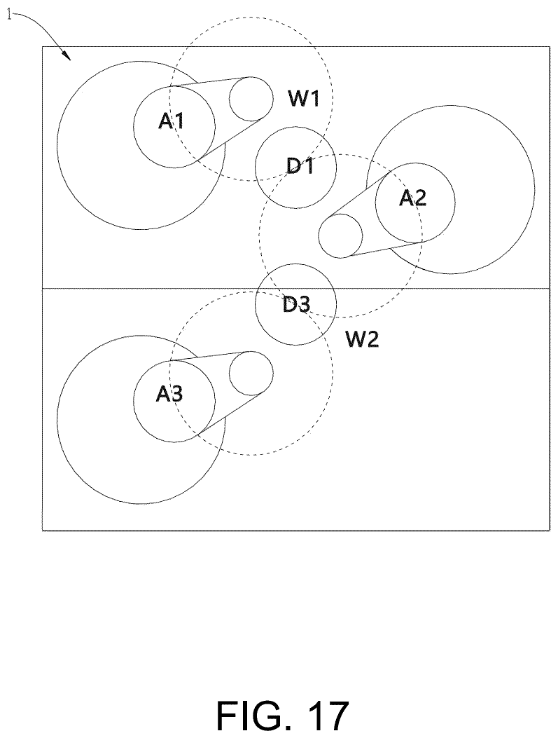

As shown in FIG. 17, in this embodiment, movement trajectories of the centers of the polishing heads 22 of two polishing modules 2 in each polishing unit 1 have only one intersection D1, and movement trajectories of the centers of the polishing heads 22 of two polishing modules 2 in a diagonal direction of adjacent polishing units 1 have only one intersection D3.

The axis of the first fixed working station 3 is located at the intersection D1, and the axis of the second fixed working station 4 is located at the intersection D3.

The polishing head A1 and the polishing head A2 both pass through the first fixed working station 3 (W1). The polishing head A2 and the polishing head A3 both pass through the second fixed working station 4 (W2).

The above specific embodiments are used for explaining the invention rather than limiting the invention. Any modifications and transformations made to the invention based on the spirit and protection scope of the claims should also fall within the protection scope of the invention.

1. A wafer polishing system, comprising:
at least two polishing units, wherein
each said polishing unit comprises at least two polishing modules and a first fixed working station, and each said polishing module comprises a polishing platform and a polishing head;
at least two said polishing heads in each said polishing unit are able to transfer wafers to the first fixed working station;
at least a second fixed working station is arranged between adjacent said polishing units;
at least two said polishing heads of adjacent said polishing units are able to transfer the wafers to the second fixed working station.

2. The wafer polishing system according to claim 1, wherein a third fixed working station is arranged between adjacent said polishing units.

3. The wafer polishing system according to claim 1, wherein movement areas of the polishing heads of two said polishing modules of adjacent said polishing units have an overlap, and the second fixed working station is located in the overlap.

4. The wafer polishing system according to claim 3, wherein an axis of the second fixed working station is located in the overlap.

5. The wafer polishing system according to claim 3, wherein the second fixed working station is a loading and unloading platform, or a combination of the loading and unloading platform and a cleaning component, or a cleaning station, or a robot arm.

6. The wafer polishing system according to claim 3, wherein an axis of the second fixed working station and an axis of a third working station are located at intersections of the overlap.

7. The wafer polishing system according to claim 2, wherein the second fixed working station and the third fixed working station are respectively a cleaning station and a loading and unloading platform.

8. The wafer polishing system according to claim 2, wherein a movement trajectory of each said polishing head is arc or circular, movement trajectories of centers of the polishing heads of two said polishing modules in each said polishing unit have only one intersection, and an overlap of the movement trajectories of the centers of the two polishing heads in a diagonal direction of adjacent said polishing units is eye-shaped.

9. The wafer polishing system according to claim 8, wherein an axis of the second fixed working station and an axis of the third fixed working station are located at intersections of the overlap of the movement trajectories of the centers of the polishing heads.

10. The wafer polishing system according to claim 8, wherein at least a cleaning station and a loading and unloading platform are arranged in the movement trajectories of the centers of the polishing heads of the polishing unit at an end of the wafer polishing system.

11. The wafer polishing system according to claim 1, wherein an overlap of movement trajectories of centers of the polishing heads of two said polishing modules in each said polishing unit is eye-shaped, and an overlap of movement trajectories of centers of the polishing heads of the two polishing modules in a diagonal direction of adjacent said polishing units is eye-shaped.

12. The wafer polishing system according to claim 1, wherein an overlap of movement trajectories of centers of the polishing heads of two said polishing module in each polishing unit is eye-shaped, and movement trajectories of centers of the polishing heads of the two polishing modules in a diagonal direction of adjacent said polishing units has only one intersection.

13. The wafer polishing system according to claim 1, wherein movement trajectories of centers of the polishing heads of two said polishing module in each said polishing unit has only one intersection, and movement trajectories of centers of the polishing heads of the two polishing modules in a diagonal direction of adjacent said polishing units is has only one intersection.

14. The wafer polishing system according to claim 1, wherein a movement area of the polishing head of at least one said polishing module of each said polishing unit passes through an axis of the first fixed working station and an axis of the second fixed working station.

15. The wafer polishing system according to claim 1, wherein at least two said first fixed working stations are arranged in each said polishing unit; the two polishing heads corresponding to only one said first fixed working station in adjacent said polishing units are arranged close to each other, and the second fixed working station is between the two polishing heads.

16. The wafer polishing system according to claim 1, wherein connecting lines between the polishing modules in adjacent said polishing units are parallel, and the second fixed working station is located between the polishing modules in a diagonal direction of adjacent said polishing units.

17. The wafer polishing system according to claim 1, wherein connecting lines between polishing modules in adjacent said polishing units intersect with each other, and the second fixed working station is close to an intersection of the connecting lines.

18. The wafer polishing system according to claim 1, wherein the polishing units are arranged in a wafer transfer direction, and a transfer interval is formed between adjacent said polishing units.

19. The wafer polishing system according to claim 1, wherein multiple said polishing units are arranged along a straight line, or an oblique line, or a bend line.

20. The wafer polishing system according to claim 1, wherein each said polishing unit is provided with two said polishing modules.

21. The wafer polishing system according to claim 1, wherein at least two said first fixed working stations are arranged in each said polishing unit; the two polishing heads corresponding to only one said first fixed working station are close to each other, and the second fixed working station is arranged between the two polishing heads.
